(19) United States
(12) Patent Application Publication
(10) Pub. No.: US 2026/0344159 A1
(43) Pub. Date: Oct. 29, 2026

(54) HIGH CHROMATIC RICHNESS LIGHT SOURCE

(71) Applicant: Guangdong Kinglong Health Lighting Technology Co.,Ltd, Zhongshan (CN)

(72) Inventor: Shiqiang YUAN, Zhongshan (CN)

(21) Appl. No.: 19/323,908

(22) Filed: Sep. 9, 2025

(30) Foreign Application Priority Data
Apr. 28, 2025 (WO) PCT/CN2025/091732
Jun. 24, 2025 (CN) 202510856934.3

(51) Int. Cl. H10H 29/851; H10H 29/852

(52) U.S. Cl. CPC H10H 29/8513; H10H 29/852

(57) ABSTRACT

A high chromatic richness light source based on differences in stimulation patterns of human cone cells between monochromatic light and mixed light perceived as the same color in the color discrimination mechanism of human eye. A visible light band from 380 nm to 780 nm is divided into three wavebands using 430 nm and 680 nm as dividing wavelength values. The design of peak emission wavelengths of LED chips and phosphors excited by the corresponding LED chips ensures richness of the peak emission wavelengths of the high chromatic richness light source of each waveband, correspondingly ensuring the chromatic richness of the high chromatic richness light source. This configuration allows the chromatic spectrum entering the human eye to converge with the chromatic spectrum of an observed object, thereby enhancing the ability of the human eye to distinguish and compare object differences, and providing a natural, realistic, and comfortable visual experience.

### BACKGROUND OF THE PRESENT INVENTION

### Field of Invention

The present invention relates to the field of light sources, and particularly to a high chromatic richness light source.

### Description of Related Arts

With the continuous development of light source technology, the quality of healthy and comfortable light color has attracted increasing attention. People have higher requirements for the color rendering quality and comfort of light sources. For example, the concept of full-spectrum illumination has been proposed to meet the requirements for comfort and color rendering quality of illumination light sources, and four-color technology has been introduced to meet the color rendering requirements of display light sources.

However, for current illumination and display light sources using LED chips, since LED chips generally have narrow emission bands and obvious peak emission wavelengths, even when using multiple LED chips in combination with phosphors in corresponding ratios, it is still difficult to achieve an overall intensity convergence between the emission spectrum of the light source and the solar spectrum within the full visible wavelength range (380 nm to 780 nm). Therefore, existing illumination and display light sources generally adopt a color rendering mechanism based on the three primary colors of red, green, and blue, and within the wavelength range of 430 nm to 680 nm, ensure color rendering quality through appropriate design of the emission intensity of the three primary color bands. In other words, even illumination light sources designed based on the concept of full-spectrum illumination only converge the emission spectrum to the solar spectrum within the wavelength range of 430 nm to 680 nm by using multiple LED chips combined with phosphors in corresponding ratios. Although the light sources designed based on the concept of full-spectrum illumination can achieve good color rendering quality, such illumination and display light sources still fail to deliver a natural, realistic, and comfortable visual experience for the human eye. This is because, for those skilled in the field of light source design and manufacturing, although they are familiar with the three-primary-color display mechanism, it is difficult for them to understand the human eye's color discrimination mechanism across different disciplines.

Specifically, there are two types of photoreceptor cells in the human retina: rod cells and cone cells. Rod cells function under low light conditions and do not have color recognition capability, thus, humans can see objects in low light but cannot distinguish colors. Under bright light conditions, cone cells are responsible for function. Our ability to perceive color is attributed to cone cells, which can absorb light waves of different lengths and transmit the information to the brain. The brain processes this information to generate color perception. Normally, there are three cone cells in the human retina that can respectively respond to red, green, and blue light, which is why red, green, and blue are referred to as the three primary colors. These three cone cells are L-cones, M-cones, and S-cones, respectively. In other words, while the color of light is related to its wavelength, color perception for the human eye results from the different response combinations of the three cone cells to light. For example, yellow light stimulates both L-cones and M-cones, which triggers the brain's perception of yellow; thus, a mixture of red and green light can be perceived as yellow by the brain even without a change in wavelength. Moreover, there are cases where different stimulation patterns of the three cone cells can still be perceived as the same color by the brain. For example, the stimulation pattern caused by monochromatic violet light and that caused by a mixture of red and blue light perceived as violet by the human eye are shown below:

| | S-cone | M-cone | L-cone |
|---|---|---|---|
| Light Source Type | Stimulation | Stimulation | Stimulation |
| Monochromatic | High | Very Low | Low |
| Violet | | | |
| Red-Blue Mixed | High | Low | High |
| Light | | | |

For color perception formed by mixed light, since chromatic spectrum entering the eye is not the same as the natural chromatic spectrum of the observed object, and there are individual differences in the peak wavelengths of the cone cells among different people (some people even have four cone cells), there is variability in how mixed light colors are perceived. This difference becomes more obvious when the stimulation pattern of the three cone cells for mixed light differs from that of monochromatic light perceived as the same color. In addition, differences in the reflective ability of objects to different color components of the mixed light can also affect the human eye's perception of the object's color. Therefore, although light sources designed based on the aforementioned full-spectrum illumination concept can achieve good color rendering quality by converging the emission spectrum with the solar spectrum in the wavelength range of 430 nm to 680 nm, their chromatic richness is still far inferior to sunlight. As a result, the chromatic spectrum entering the eye does not correspond to the natural chromatic spectrum of the viewed object, and the human eye cannot achieve a natural, realistic, and comfortable visual experience.

### SUMMARY OF THE PRESENT INVENTION

One objective of the present invention is to provide a high chromatic richness light source, wherein the high chromatic richness light source is designed based on differences in stimulation patterns of three human cone cells between monochromatic light and mixed light perceived as the same color within color discrimination mechanism of human eye. A visible light band from 380 nm to 780 nm is divided into three wavebands using 430 nm and 680 nm as dividing wavelength values, and based on the design of peak emission wavelengths of LED chips and phosphors using the corresponding LED chips as excitation sources. This ensures the richness of the peak emission wavelengths of the high chromatic richness light source in each of the wavebands, correspondingly ensuring the chromatic richness of the high chromatic richness light source. This design allows a chromatic spectrum entering the human eye to converge with the chromatic spectrum of the observed object within the color discrimination mechanism of the human eye, enhancing the ability of the human eye to distinguish and compare object differences and providing a natural, realistic, and comfortable visual experience.

Another objective of the present invention is to provide a high chromatic richness light source, wherein the high chromatic richness light source has multiple types of LED chips and multiple types of phosphors using the corresponding LED chips as excitation sources. Correspondingly, the high chromatic richness light source has at least two peak emission wavelengths generated by LED chips within a waveband greater than or equal to 380 nm and less than 430 nm, with a mutual peak wavelength difference greater than or equal to 5 nm; at least two peak emission wavelengths generated by LED chips within a waveband greater than or equal to 430 nm and less than 490 nm, with a mutual peak wavelength difference greater than or equal to 5 nm; and at least three peak emission wavelengths generated by phosphors within a waveband greater than or equal to 490 nm and less than 680 nm, with a mutual peak wavelength difference greater than or equal to 5 nm; as well as at least two peak emission wavelengths generated by LED chips within a waveband greater than or equal to 680 nm and less than or equal to 780 nm, with a mutual peak wavelength difference greater than or equal to 5 nm. This ensures the richness of the peak emission wavelengths of the high chromatic richness light source in the aforementioned three wavebands across the 380 nm to 780 nm visible light band, correspondingly ensuring the chromatic richness of the high chromatic richness light source. This design allows the chromatic spectrum entering the human eye to converge with the chromatic spectrum of the observed object within the color discrimination mechanism of the human eye, enhancing the ability of the human eye to distinguish and compare object differences and providing a natural, realistic, and comfortable visual experience.

Another objective of the present invention is to provide a high chromatic richness light source, wherein, by means of the peak emission wavelength design for both the LED chips and the phosphors that meets the aforementioned requirements, the high chromatic richness light source achieves its emission spectrum without requiring convergence with the solar spectrum. This design allows the chromatic spectrum entering the human eye to converge with the chromatic spectrum of the observed object within the color discrimination mechanism of the human eye, enhancing the ability of the human eye to distinguish and compare object differences and providing a natural, realistic, and comfortable visual experience, thus, simplifying the ratio calculation of the LED chips and the phosphors, making it easy to implement.

Another objective of the present invention is to provide a high chromatic richness light source, wherein the high chromatic richness light source does not require convergence with the solar spectrum in its emission spectrum to enable the human eye to achieve a natural, realistic, and comfortable visual experience. In other words, the design of the peak emission wavelengths of the LED chips and the phosphors in the high chromatic richness light source departs from the conventional design concept of full-spectrum lighting that requires converging the emission spectrum with the solar spectrum. While being easy to implement, this design ensures the diversity of the emission spectrum of the high chromatic richness light source, thereby allowing it to adapt to different application scenarios.

Another objective of the present invention is to provide a high chromatic richness light source, based on the color discrimination mechanism of the human eye, although the stimulation patterns of the three cone cell types tend to be similar for monochromatic light and mixed light perceived as the same color within the 430 nm to 680 nm waveband, differences in the reflective capability of objects to different color components of mixed light also affect the human eye's perception of the object's true color. Therefore, based on the design concept of ensuring the chromatic richness of the high chromatic richness light source to make the chromatic spectrum entering the eye converge with the chromatic spectrum of the observed object within the color discrimination mechanism of the human eye, and based on the peak emission wavelength design of the LED chips and the phosphors meeting the aforementioned requirements, the present invention ensures the richness of the peak emission wavelengths of the high chromatic richness light source within the 430 nm to 680 nm waveband and the entire visible light range including this waveband. Correspondingly, when using the high chromatic richness light source as an illumination source to irradiate an object of any chromatic spectrum, the object can reflect light converging with its chromatic spectrum, thereby providing a natural, realistic, and comfortable visual experience when using the high chromatic richness light source as an illumination source.

Another objective of the present invention is to provide a high chromatic richness light source, based on the color discrimination mechanism of the human eye, the stimulation patterns of the three cone cell types are not the same for monochromatic light and mixed light perceived as the same color within the 380 nm to 430 nm waveband. Differences in the reflective capability of objects to different color components of mixed light also affect the human eye's perception of the object's true color. Therefore, based on the design concept of ensuring the chromatic richness of the high chromatic richness light source to make the chromatic spectrum entering the eye converge with the chromatic spectrum of the observed object within the color discrimination mechanism of the human eye, and based on the peak emission wavelength design of the LED chips and the phosphors meeting the aforementioned requirements, the present invention ensures the richness of the peak emission wavelengths of the high chromatic richness light source within the 380 nm to 430 nm waveband and the entire visible light range including this band. Correspondingly, when using the high chromatic richness light source as an illumination source to irradiate an object of any chromatic spectrum, the object can reflect light converging with its chromatic spectrum, thereby providing a natural, realistic, and comfortable visual experience when using the high chromatic richness light source as an illumination source.

Another objective of the present invention is to provide a high chromatic richness light source, based on the design concept of ensuring the chromatic richness of the high chromatic richness light source to make the chromatic spectrum entering the eye converge with the chromatic spectrum of the observed object within the color discrimination mechanism of the human eye, and based on the peak emission wavelength design of the LED chips and the phosphors meeting the aforementioned requirements, the present invention also ensures the richness of the peak emission wavelengths of the high chromatic richness light source within the 680 nm to 780 nm waveband and the entire visible light range including this band. This satisfies the visual experience arising from the human eye's adaptation to sunlight, thereby obtaining a natural, realistic, and comfortable visual experience when using the high chromatic richness light source as a display or illumination source.

Another objective of the present invention is to provide a high chromatic richness light source, wherein the high chromatic richness light source also has at least two peak emission wavelengths generated by phosphors within a waveband greater than 780 nm and less than or equal to 850 nm, with a mutual peak wavelength difference greater than or equal to 5 nm. This further satisfies non-visual sensations arising from the adaptation of the human eye and skin to sunlight.

Another objective of the present invention is to provide a high chromatic richness light source, wherein the high chromatic richness light source has at least two lighting modes based on color temperature adjustment or selection requirements, wherein in at least one of the lighting mode, the peak emission wavelengths of the LED chips emitting light and the phosphors encapsulated together with the LED chips meet the aforementioned design requirements of the peak emission wavelengths for the LED chips and the phosphors, thereby achieving a natural, realistic, and comfortable visual experience in at least one lighting mode of the high chromatic richness light source.

To achieve at least one of the above objectives, the present invention provides a high chromatic richness light source, wherein the high chromatic richness light source has at least two peak emission wavelengths generated by LED chips within a waveband greater than or equal to 380 nm and less than 430 nm, with a mutual peak wavelength difference greater than or equal to 5 nm; at least two peak emission wavelengths generated by LED chips within a waveband greater than or equal to 430 nm and less than 490 nm, with a mutual peak wavelength difference greater than or equal to 5 nm; and at least three peak emission wavelengths generated by phosphors within a waveband greater than or equal to 490 nm and less than 680 nm, with a mutual peak wavelength difference greater than or equal to 5 nm; as well as at least two peak emission wavelengths generated by LED chips within a waveband greater than or equal to 680 nm and less than or equal to 780 nm, with a mutual peak wavelength difference greater than or equal to 5 nm, wherein when the high chromatic richness light source has at least two lighting modes, the LED chips are defined as light-emitting LED chips that operate in at least one lighting mode, and the phosphors are defined as phosphors packaged onto the light-emitting LED chips.

In one embodiment, wherein the at least two peak emission wavelengths generated by LED chips within a waveband greater than or equal to 380 nm and less than 430 nm, with a mutual peak wavelength difference greater than or equal to 5 nm, are located in different wavebands among the following five wavebands: a waveband greater than or equal to 380 nm and less than 390 nm, a waveband greater than or equal to 390 nm and less than 400 nm, a waveband greater than or equal to 400 nm and less than 410 nm, a waveband greater than or equal to 410 nm and less than 420 nm, and a waveband greater than or equal to 420 nm and less than 430 nm.

In one embodiment, wherein the at least two peak emission wavelengths generated by LED chips within a waveband greater than or equal to 430 nm and less than 490 nm, with a mutual peak wavelength difference greater than or equal to 5 nm, are located in different wavebands among the following six wavebands: a waveband greater than or equal to 430 nm and less than 440 nm, a waveband greater than or equal to 440 nm and less than 450 nm, a waveband greater than or equal to 450 nm and less than 460 nm, a waveband greater than or equal to 460 nm and less than 470 nm, a waveband greater than or equal to 470 nm and less than 480 nm, and a waveband greater than or equal to 480 nm and less than 490 nm.

In one embodiment, wherein a maximum difference between the at least three peak emission wavelengths generated by phosphors within a waveband greater than or equal to 490 nm and less than 680 nm, with a mutual peak wavelength difference greater than or equal to 5 nm, is greater than or equal to 50 nm, that is, a difference between a minimum peak emission wavelength and a maximum peak emission wavelength is greater than or equal to 50 nm.

In one embodiment, wherein the at least two peak emission wavelengths generated by LED chips within a waveband greater than or equal to 680 nm and less than or equal to 780 nm, with a mutual peak wavelength difference greater than or equal to 5 nm, are located in different wavebands among the following ten wavebands: a waveband greater than or equal to 680 nm and less than 690 nm, a waveband greater than or equal to 690 nm and less than 700 nm, a waveband greater than or equal to 700 nm and less than 710 nm, a waveband greater than or equal to 710 nm and less than 720 nm, a waveband greater than or equal to 720 nm and less than 730 nm, a waveband greater than or equal to 730 nm and less than 740 nm, a waveband greater than or equal to 740 nm and less than 750 nm, a waveband greater than or equal to 750 nm and less than 760 nm, a waveband greater than or equal to 760 nm and less than 770 nm, and a waveband greater than or equal to 770 nm and less than or equal to 780 nm.

In one embodiment, wherein the high chromatic richness light source has four LED chips with peak emission wavelengths greater than or equal to 380 nm and less than 430 nm, four LED chips with peak emission wavelengths greater than or equal to 430 nm and less than 490 nm, and six LED chips with peak emission wavelengths greater than or equal to 680 nm and less than or equal to 780 nm.

In one embodiment, wherein the four LED chips with peak emission wavelengths greater than or equal to 380 nm and less than 430 nm have peak emission wavelengths respectively located in the waveband greater than or equal to 380 nm and less than 390 nm, the waveband greater than or equal to 390 nm and less than 400 nm, the waveband greater than or equal to 400 nm and less than 410 nm, and the waveband greater than or equal to 410 nm and less than 420 nm.

In one embodiment, wherein among the four LED chips with peak emission wavelengths greater than or equal to 380 nm and less than 430 nm, the LED chip with peak emission wavelength located within the waveband greater than or equal to 380 nm and less than 390 nm has a power higher than that of any one of the other three LED chips.

In one embodiment, in order of increasing peak emission wavelength, a quantity ratio of the four LED chips with peak emission wavelengths greater than or equal to 380 nm and less than 430 nm is 2.4:1.4:1.2:1.

In one embodiment, wherein the four LED chips with peak emission wavelengths greater than or equal to 430 nm and less than 490 nm have peak emission wavelengths respectively located in the waveband greater than or equal to 430 nm and less than 440 nm, the waveband greater than or equal to 440 nm and less than 450 nm, the waveband greater than or equal to 450 nm and less than 460 nm, and the waveband greater than or equal to 470 nm and less than 480 nm.

In one embodiment, in order of increasing peak emission wavelength, a quantity ratio of the four LED chips with peak emission wavelengths greater than or equal to 430 nm and less than 490 nm is 1:1:1:1.

In one embodiment, wherein the six LED chips with peak emission wavelengths greater than or equal to 680 nm and less than or equal to 780 nm have peak emission wavelengths respectively located in the waveband greater than or equal to 700 nm and less than 710 nm, the waveband greater than or equal to 710 nm and less than 720 nm, the waveband greater than or equal to 730 nm and less than 740 nm, the waveband greater than or equal to 740 nm and less than 750 nm, the waveband greater than or equal to 750 nm and less than 760 nm, and the waveband greater than or equal to 770 nm and less than or equal to 780 nm.

In one embodiment, wherein among the six LED chips with peak emission wavelengths greater than or equal to 680 nm and less than or equal to 780 nm, the LED chip with peak emission wavelengths located within the waveband greater than or equal to 770 nm and less than or equal to 780 nm outnumber the LED chips in any other single waveband of the other five.

In one embodiment, wherein in order of increasing peak emission wavelength, a quantity ratio of the six LED chips with peak emission wavelengths greater than or equal to 680 nm and less than or equal to 780 nm is 1.3:1.6:1.6:1:3:5.

In one embodiment, wherein the high chromatic richness light source has five phosphors with peak emission wavelengths greater than or equal to 490 nm and less than 680 nm.

In one embodiment, wherein the five phosphors with peak emission wavelengths greater than or equal to 490 nm and less than 680 nm are the phosphors with peak emission wavelengths of 494 nm, 495 nm, 525 nm, 535 nm, and 655 nm, respectively.

In one embodiment, wherein in order of increasing peak emission wavelength, the weight ratio of the five phosphors with peak emission wavelengths greater than or equal to 490 nm and less than 680 nm is 0.22:0.22:0.55:5.94:0.887.

In one embodiment, wherein a power ratio between the four LED chips with peak emission wavelengths greater than or equal to 380 nm and less than 430 nm, the four LED chips with peak emission wavelengths greater than or equal to 430 nm and less than 490 nm, and the six LED chips with peak emission wavelengths greater than or equal to 680 nm and less than or equal to 780 nm is 1:10.3:3.7.

In one embodiment, wherein the high chromatic richness light source further has at least two phosphors with peak emission wavelengths greater than 780 nm and less than or equal to 850 nm, and a maximum difference between peak emission wavelengths of the different phosphors is greater than or equal to 30 nm, that is, a peak emission wavelength difference between a phosphor with the smallest peak emission wavelength and a phosphor with the largest peak emission wavelength is greater than or equal to 30 nm.

In one embodiment, wherein the high chromatic richness light source further has at least one phosphor with a peak emission wavelength greater than or equal to 680 nm and less than or equal to 780 nm.

In one embodiment, wherein the high chromatic richness light source has seven phosphors with peak emission wavelengths greater than or equal to 490 nm and less than 680 nm, one phosphor with a peak emission wavelength greater than or equal to 680 nm and less than or equal to 780 nm, and three phosphors with peak emission wavelengths greater than 780 nm and less than or equal to 850 nm.

In one embodiment, wherein the seven phosphors with peak emission wavelengths greater than or equal to 490 nm and less than 680 nm are specifically phosphors with peak emission wavelengths of 494 nm, 495 nm, 525 nm, 535 nm, 605 nm, 655 nm, and 675 nm, respectively; the one phosphor with a peak emission wavelength greater than or equal to 680 nm and less than or equal to 780 nm is specifically phosphor with a peak emission wavelength of 733 nm; the three phosphors with peak emission wavelengths greater than 780 nm and less than or equal to 850 nm are specifically the phosphors with peak emission wavelengths of 795 nm, 821 nm, and 850 nm, respectively.

In one embodiment, wherein in order of increasing peak emission wavelength, a specific weight ratio of the eleven phosphors is 0.27:0.097:2.86:14.28:2.4:0.67:0.84:4:2:1:1.

In one embodiment, wherein the LED chips with peak emission wavelengths greater than or equal to 430 nm and less than 490 nm are encapsulated together with the corresponding phosphors, the LED chips with peak emission wavelengths greater than or equal to 380 nm and less than 430 nm are encapsulated together with at least one of the phosphor.

In one embodiment, wherein LED packages serve as packaging carriers for the LED chips and the phosphors, in the LED packages encapsulating with the LED chips with peak emission wavelengths greater than or equal to 430 nm and less than 490 nm, the corresponding phosphors are also encapsulated, while in the LED packages encapsulating with the LED chips with peak emission wavelengths greater than or equal to 380 nm and less than 430 nm, the LED chips with peak emission wavelengths greater than or equal to 430 nm and less than 490 nm are also encapsulated.

In one embodiment, wherein the LED chips with peak emission wavelengths greater than or equal to 680 nm and less than or equal to 780 nm are individually encapsulated, corresponding to the LED packages encapsulating the LED chips with peak emission wavelengths greater than or equal to 680 nm and less than or equal to 780 nm, neither the phosphors nor the LED chips with peak emission wavelengths greater than or equal to 380 nm and less than 430 nm or the LED chips with peak emission wavelengths greater than or equal to 430 nm and less than 490 nm are encapsulated.

In one embodiment, wherein in the LED packages encapsulating the LED chips with peak emission wavelengths greater than or equal to 680 nm and less than or equal to 780 nm, the LED chips with peak emission wavelengths greater than or equal to 430 nm and less than 490 nm are also encapsulated.

In one embodiment, wherein LED packages serve as packaging carriers for the LED chips and the phosphors, in the LED packages encapsulating the LED chips with peak emission wavelengths greater than or equal to 430 nm and less than 490 nm, the corresponding phosphors are also encapsulated, while the LED packages encapsulating the LED chips with peak emission wavelengths greater than or equal to 380 nm and less than 430 nm, the LED chips with peak emission wavelengths greater than or equal to 680 nm and less than or equal to 780 nm and the corresponding phosphors are also encapsulated, and at least a portion of the LED packages are encapsulated with only the LED chips with peak emission wavelengths greater than or equal to 680 nm and less than or equal to 780 nm among the types of LED chips being encapsulated.

In one embodiment, at least a portion of the LED packages that are encapsulated only with the LED chips having peak emission wavelengths greater than or equal to 680 nm and less than or equal to 780 nm among the types of the LED chips being encapsulated are further encapsulated together with the corresponding phosphors.

The further objects and advantages of the present invention will be fully embodied through the understanding of the subsequent description and the drawings.

### BRIEF DESCRIPTION OF THE DRAWINGS

FIG. 1 is an emission spectrum of a high chromatic richness light source according to one embodiment of the present invention.

FIG. 2 is an emission spectrum of a high chromatic richness light source according to another embodiment of the present invention.

FIG. 3 is an emission spectrum of a high chromatic richness light source according to another embodiment of the present invention.

FIG. 4A is an exemplary packaging structure of a high chromatic richness light source according to one embodiment of the present invention.

FIG. 4B is another exemplary packaging structure of the high chromatic richness light source in the aforementioned embodiment

FIG. 4C is still another exemplary packaging structure of the high chromatic richness light source in the aforementioned embodiment.

### DETAILED DESCRIPTION OF THE PREFERRED EMBODIMENT

The following description is used to disclose the present invention so that those skilled in the art can implement the present invention. The preferred embodiments in the following description are only given by way of example, and other obvious variations can be conceived by those skilled in the art. The basic principles of the present invention as defined in the following description can be applied to other embodiments, variants, improvements, equivalents, and other technical solutions without departing from the spirit and scope of the present invention.

It can be understood that the term “one” should be understood as “at least one” or “one or more”, that is, in one embodiment, the number of an element may be one, while in another embodiment, the number of the element may be multiple, and the term “one” should not be construed as a limitation on quantity.

The present invention provides a high chromatic richness light source, wherein the high chromatic richness light source is designed based on differences in stimulation patterns of three human cone cells between monochromatic light and mixed light perceived as the same color within the color discrimination mechanism of the human eye. A visible light band from 380 nm to 780 nm is divided into three wavebands using 430 nm and 680 nm as dividing wavelength values, and based on the design of peak emission wavelengths of LED chips and phosphors using the corresponding LED chips as excitation sources. This ensures the richness of the peak emission wavelengths of the high chromatic richness light source in each of the wavebands, correspondingly ensuring the chromatic richness of the high chromatic richness light source. This design allows the chromatic spectrum entering the human eye to converge with the chromatic spectrum of the observed object within the color discrimination mechanism of the human eye, enhancing the ability of the human eye to distinguish and compare object differences and providing a natural, realistic, and comfortable visual experience.

Specifically, the high chromatic richness light source has multiple types of LED chips and multiple types of phosphors using the corresponding LED chips as excitation light sources, and correspondingly has at least two peak emission wavelengths generated by LED chips within a waveband greater than or equal to 380 nm and less than 430 nm, with a mutual peak wavelength difference greater than or equal to 5 nm; at least two peak emission wavelengths generated by LED chips within a waveband greater than or equal to 430 nm and less than 490 nm, with a mutual peak wavelength difference greater than or equal to 5 nm; and at least three peak emission wavelengths generated by phosphors within a waveband greater than or equal to 490 nm and less than 680 nm, with a mutual peak wavelength difference greater than or equal to 5 nm; as well as at least two peak emission wavelengths generated by LED chips within a waveband greater than or equal to 680 nm and less than or equal to 780 nm, with a mutual peak wavelength difference greater than or equal to 5 nm. This ensures the richness of the peak emission wavelengths of the high chromatic richness light source in the aforementioned three wavebands across the 380 nm to 780 nm visible light band, correspondingly ensuring the chromatic richness of the high chromatic richness light source. This design allows the chromatic spectrum entering the human eye to converge with the chromatic spectrum of the observed object within the color discrimination mechanism of the human eye, enhancing the ability of the human eye to distinguish and compare object differences and providing a natural, realistic, and comfortable visual experience.

It is worth mentioning that, based on the peak emission wavelength design of the LED chips and the phosphors meeting the aforementioned requirements, the high chromatic richness light source does not require convergence with the solar spectrum in its emission spectrum. This design allows the chromatic spectrum entering the human eye to converge with the chromatic spectrum of the observed object within the color discrimination mechanism of the human eye, enhancing the ability of the human eye to distinguish and compare object differences and providing a natural, realistic, and comfortable visual experience, thus, simplifying the ratio calculation of the LED chips and the phosphors, making it easy to implement.

Specifically, the aforementioned limitation of “mutual peak wavelength difference greater than or equal to 5 nm” does not restrict the peak wavelength differences between all emission peaks within the aforementioned three wavebands. For example, when the high chromatic richness light source has four peak emission wavelengths generated by LED chips within a waveband greater than or equal to 380 nm and less than 430 nm, even if only two of the peak emission wavelengths satisfy the condition of having a mutual peak wavelength difference greater than or equal to 5 nm, it still conforms to the description of “having at least two peak emission wavelengths generated by LED chips within a waveband greater than or equal to 380 nm and less than 430 nm, with a mutual peak wavelength difference greater than or equal to 5 nm”. Therefore, the same peak emission wavelength can be generated by the different of the LED chips or the phosphors, and different peak emission wavelengths can also be generated by the same type of the LED chip or the phosphor, for example, at least two different peak emission wavelengths generated by a multi-quantum-well LED chip. However, based on this limitation method, the peak emission wavelength design of the LED chips and the phosphors that meet the aforementioned requirements can ensure the dispersion and quantity of the peak emission wavelengths of the high chromatic richness light source in the aforementioned three wavebands, thereby ensuring the richness of the peak emission wavelengths of the high chromatic richness light source in the three wavebands.

In addition, the high chromatic richness light source can provide a natural, realistic, and comfortable visual experience for the human eye without requiring convergence design with the solar spectrum, that is to say, the high chromatic richness light source of the present invention, in the design of the peak emission wavelengths of the LED chips and the phosphors, departs from the design idea in the traditional full-spectrum lighting concept that requires the emission spectrum to converge toward the solar spectrum. While being easy to implement, the design ensures the diversity of the emission spectrum of the high chromatic richness light source, thereby allowing it to adapt to different application scenarios.

Specifically, in the high chromatic richness light source of the present invention, the at least two peak emission wavelengths generated by LED chips within a waveband greater than or equal to 380 nm and less than 430 nm, with mutual peak wavelength difference greater than or equal to 5 nm, are preferably located in different wavebands among the following five wavebands: a waveband greater than or equal to 380 nm and less than 390 nm, the waveband greater than or equal to 390 nm and less than 400 nm, a waveband greater than or equal to 400 nm and less than 410 nm, a waveband greater than or equal to 410 nm and less than 420 nm, and a waveband greater than or equal to 420 nm and less than 430 nm. In this way, the richness of the peak emission wavelengths of the high chromatic richness light source in the 380 nm to 430 nm waveband is further ensured.

It is worth mentioning that, based on the color discrimination mechanism of the human eye, the stimulation patterns of the three cone cell types are not the same for monochromatic light and mixed light perceived as the same color within the 380 nm to 430 nm waveband. Differences in the reflective capability of objects to different color components of mixed light also affect the human eye's perception of the object's true color. Therefore, based on the design concept of ensuring the chromatic richness of the high chromatic richness light source to make the chromatic spectrum entering the eye converge with the chromatic spectrum of the observed object within the color discrimination mechanism of the human eye, and based on the peak emission wavelength design of the LED chips and the phosphors meeting the aforementioned requirements, the present invention ensures the richness of the peak emission wavelengths of the high chromatic richness light source within the 380 nm to 430 nm waveband and the entire visible light range including this band. Correspondingly, when using the high chromatic richness light source as an illumination source to irradiate an object of any chromatic spectrum, the object can reflect light converging with its chromatic spectrum, thereby providing a natural, realistic, and comfortable visual experience when using the high chromatic richness light source as an illumination source.

Furthermore, in the high chromatic richness light source of the present invention, the at least two peak emission wavelengths generated by LED chips within a waveband greater than or equal to 430 nm and less than 490 nm, with a mutual peak wavelength difference greater than or equal to 5 nm, are preferably located in different wavebands among the following six wavebands: a waveband greater than or equal to 430 nm and less than 440 nm, a waveband greater than or equal to 440 nm and less than 450 nm, a waveband greater than or equal to 450 nm and less than 460 nm, a waveband greater than or equal to 460 nm and less than 470 nm, a waveband greater than or equal to 470 nm and less than 480 nm, and a waveband greater than or equal to 480 nm and less than 490 nm. Among the at least three peak emission wavelengths generated by phosphors within a waveband greater than or equal to 490 nm and less than 680 nm, with a mutual peak wavelength difference greater than or equal to 5 nm from each other, a maximum peak wavelength difference is preferably greater than or equal to 50 nm, that is, a difference between the minimum peak emission wavelength and the maximum peak emission wavelength is greater than or equal to 50 nm. In this way, the richness of the peak emission wavelengths of the high chromatic richness light source within the waveband of 430 nm to 680 nm is further ensured.

It is worth mentioning that although the stimulation patterns of the three cone cell types tend to be similar for monochromatic light and mixed light perceived as the same color within the 430 nm to 680 nm waveband, differences in the reflective capability of objects to different color components of mixed light also affect the human eye's perception of the object's true color. for a yellow lemon, the reflectance of yellow light is strong, making it bright yellow in sunlight, but the reflectance of red-green mixed light that can be recognized as yellow by the human eye is relatively weak and shows some differences, thus usually appearing dark yellow or yellow-greenish under traditional LED lighting. Therefore, based on the design concept of ensuring the chromatic richness of the high chromatic richness light source to make the chromatic spectrum entering the eye converge with the chromatic spectrum of the observed object within the color discrimination mechanism of the human eye, and based on the peak emission wavelength design of the LED chips and the phosphors meeting the aforementioned requirements, the present invention ensures the richness of the peak emission wavelengths of the high chromatic richness light source within the 430 nm to 680 nm waveband and the entire visible light range including this waveband. Correspondingly, when using the high chromatic richness light source as an illumination source to irradiate an object of any chromatic spectrum, the object can reflect light converging with its chromatic spectrum, thereby providing a natural, realistic, and comfortable visual experience when using the high chromatic richness light source as an illumination source.

Furthermore, in the high chromatic richness light source of the present invention, the at least two peak emission wavelengths generated by LED chips within a waveband greater than or equal to 680 nm and less than or equal to 780 nm, with a mutual peak wavelength difference greater than or equal to 5 nm, are preferably located in different wavebands among the following ten wavebands: a waveband greater than or equal to 680 nm and less than 690 nm, a waveband greater than or equal to 690 nm and less than 700 nm, a waveband greater than or equal to 700 nm and less than 710 nm, a waveband greater than or equal to 710 nm and less than 720 nm, a waveband greater than or equal to 720 nm and less than 730 nm, a waveband greater than or equal to 730 nm and less than 740 nm, a waveband greater than or equal to 740 nm and less than 750 nm, a waveband greater than or equal to 750 nm and less than 760 nm, a waveband greater than or equal to 760 nm and less than 770 nm, and a waveband greater than or equal to 770 nm and less than or equal to 780 nm. In this way, the richness of the peak emission wavelengths of the high chromatic richness light source within the waveband of 680 nm to 780 nm is ensured, and satisfying the visual experience arising from the human eye's adaptation to sunlight, thereby obtaining a natural, realistic, and comfortable visual experience when using the high chromatic richness light source as a display or illumination source.

For example, in one embodiment of the present invention, taking the LED chip with a single quantum well as an example, the high chromatic richness light source has four of the LED chips with peak emission wavelengths greater than or equal to 380 nm and less than 430 nm, four of the LED chips with peak emission wavelengths greater than or equal to 430 nm and less than 490 nm, and five of the phosphors with peak emission wavelengths greater than or equal to 490 nm and less than 680 nm, as well as six of the LED chips with peak emission wavelengths greater than or equal to 680 nm and less than or equal to 780 nm.

Specifically, in this embodiment of the present invention, the four LED chips with peak emission wavelengths greater than or equal to 380 nm and less than 430 nm have peak emission wavelengths respectively located within a waveband greater than or equal to 380 nm and less than 390 nm, the waveband greater than or equal to 390 nm and less than 400 nm, the waveband greater than or equal to 400 nm and less than 410 nm, and the waveband greater than or equal to 410 nm and less than 420 nm.

The four LED chips with peak emission wavelengths greater than or equal to 430 nm and less than 490 nm have peak emission wavelengths respectively located within the waveband of greater than or equal to 430 nm and less than 440 nm, the waveband greater than or equal to 440 nm and less than 450 nm, the waveband greater than or equal to 450 nm and less than 460 nm, and the waveband greater than or equal to 470 nm and less than 480 nm.

The six LED chips with peak emission wavelengths greater than or equal to 680 nm and less than or equal to 780 nm have peak emission wavelengths respectively located within the waveband of greater than or equal to 700 nm and less than 710 nm, the waveband greater than or equal to 710 nm and less than 720 nm, the waveband greater than or equal to 730 nm and less than 740 nm, the waveband greater than or equal to 740 nm and less than 750 nm, the waveband greater than or equal to 750 nm and less than 760 nm, and the waveband greater than or equal to 770 nm and less than or equal to 780 nm.

Specifically, in this embodiment of the present invention, the five phosphors with peak emission wavelengths greater than or equal to 490 nm and less than 680 nm are specifically phosphors with peak emission wavelengths of 494 nm, 495 nm, 525 nm, 535 nm, and 655 nm.

It can be understood that, when at least two of the phosphors have different peak emission wavelengths within a peak emission wavelength difference range of less than 5 nm, the emission peaks generated by the two phosphors are relatively wide, which is advantageous for ensuring the richness of the peak emission wavelengths of the high chromatic richness light source in the corresponding waveband.

Furthermore, in this embodiment of the present invention, among the four LED chips with peak emission wavelengths greater than or equal to 380 nm and less than 430 nm, the LED chip having a peak emission wavelength located within a waveband greater than or equal to 380 nm and less than 390 nm has a power higher than that of any one of the other three LED chips, so as to facilitate strengthening the intensity of the peak emission wavelengths of the high chromatic richness light source in the violet waveband, thereby ensuring that the peak emission wavelengths of the high chromatic richness light source within the waveband of 380 nm to 430 nm have appropriate intensity distribution while ensuring the richness of the peak emission wavelengths of the high chromatic richness light source within the waveband of 380 nm to 430 nm.

Specifically, in this embodiment of the present invention, in order of increasing peak emission wavelength, a quantity ratio of the four LED chips with peak emission wavelengths greater than or equal to 380 nm and less than 430 nm is 2.4:1.4:1.2:1, and the specific quantities are 12, 7, 6, and 5, respectively.

Furthermore, in this embodiment of the present invention, among the six LED chips with peak emission wavelengths greater than or equal to 680 nm and less than or equal to 780 nm, the quantity of the LED chips with a peak emission wavelength located within a waveband greater than or equal to 770 nm and less than or equal to 780 nm is greater than that of any one of the other five LED chips, so as to enable the peak emission wavelengths of the high chromatic richness light source to have an appropriate intensity distribution in this waveband while ensuring the richness of the peak emission wavelengths of the high chromatic richness light source within the waveband of 680 nm to 780 nm, which is advantageous for enhancing the visual perception generated by the human eye's adaptability to sunlight, thereby obtaining a natural, realistic, and comfortable visual experience when the high chromatic richness light source is used as a display light source or an illumination light source.

Specifically, in this embodiment of the present invention, in order of increasing peak emission wavelength, a quantity ratio of the six LED chips with peak emission wavelengths greater than or equal to 680 nm and less than or equal to 780 nm is 1.3:1.6:1.6:1:3:5, and the specific quantities are 13, 16, 16, 10, 30, and 50, respectively.

Furthermore, based on the corresponding color temperature design requirement, in this embodiment of the present invention, in order of increasing peak emission wavelength, a quantity ratio of the four LED chips with peak emission wavelengths greater than or equal to 430 nm and less than 490 nm is 1:1:1:1, and the specific quantity of each is 84; a weight ratio of the five phosphors with peak emission wavelengths greater than or equal to 490 nm and less than 680 nm is: 0.22:0.22:0.55:5.94:0.887. Thus, while satisfying the corresponding color temperature design requirement, the richness of the peak emission wavelengths of the high chromatic richness light source within the waveband of 430 nm to 680 nm is ensured, and the peak emission wavelengths of the high chromatic richness light source have an appropriate intensity distribution in this waveband.

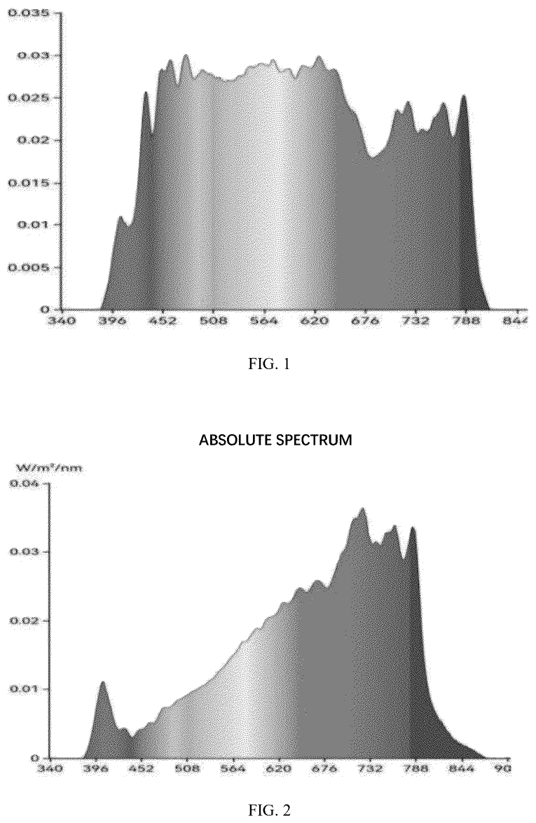

Furthermore, in this embodiment of the present invention, based on the ratio design of the LED chips and the phosphors satisfying the aforementioned requirements, when a power ratio of the four LED chips with peak emission wavelengths greater than or equal to 380 nm and less than 430 nm, the four LED chips with peak emission wavelengths greater than or equal to 430 nm and less than 490 nm, and the six LED chips with peak emission wavelengths greater than or equal to 680 nm and less than or equal to 780 nm is 1:10.3:3.7, the high chromatic richness light source can form an emission spectrum corresponding to FIG. 1 at a color temperature of 5200K, so that the chromatic spectra of the high chromatic richness light source have high richness and appropriate intensity distribution throughout the entire visible region, thereby facilitating reflection of light converging to the chromatic spectrum of an object when the high chromatic richness light source is used as an illumination light source to illuminate an object of any chromatic spectrum, and thus obtaining a natural, realistic, and comfortable visual experience when the high chromatic richness light source is used as an illumination light source.

Furthermore, in this embodiment of the present invention, based on the corresponding color temperature design requirement, the component ratio of the phosphors and the power ratio of the LED chips in different wavebands are adjusted relative to the high chromatic richness light source in the previous embodiment.

Specifically, in this embodiment of the present invention, the high chromatic richness light source further has at least two peak emission wavelengths generated by phosphors within a waveband greater than or equal to 780 nm and less than or equal to 850 nm, with a mutual peak wavelength difference greater than or equal to 5 nm, so as to further satisfy non-visual sensations arising from the adaptation of the human eye and skin to sunlight. Wherein, among the at least two phosphors with peak emission wavelengths greater than 780 nm and less than or equal to 850 nm, with a mutual peak wavelength difference greater than or equal to 5 nm from each other, a maximum difference between the peak emission wavelengths of the different phosphors is preferably greater than or equal to 30 nm, that is, a peak emission wavelength difference between a phosphor with the smallest peak emission wavelength and a phosphor with the largest peak emission wavelength is greater than or equal to 30 nm, so as to facilitate ensuring the continuity of the peak emission wavelengths of the high chromatic richness light source in the waveband of 780 nm to 850 nm, thereby satisfying the non-visual experience generated by the human eye and skin in adaptation to sunlight.

Specifically, in this embodiment of the present invention, the high chromatic richness light source has at least two phosphors with peak emission wavelengths greater than or equal to 780 nm and less than or equal to 850 nm, so that at least two peak emission wavelengths with a mutual peak wavelength difference greater than or equal to 5 nm are generated by phosphors in the waveband greater than or equal to 780 nm and less than 850 nm, and among the at least two phosphors with peak emission wavelengths greater than 780 nm and less than or equal to 850 nm, a maximum difference between the peak emission wavelengths of different phosphors is greater than or equal to 30 nm, that is, the peak emission wavelength difference between the phosphor having the smallest peak emission wavelength and the phosphor having the largest peak emission wavelength is greater than or equal to 30 nm.

In addition, in this embodiment of the present invention, the high chromatic richness light source also has at least one phosphor with a peak emission wavelength greater than or equal to 680 nm and less than or equal to 780 nm, so as to further enrich the richness of the peak emission wavelengths of the high chromatic richness light source in this waveband and enhance the intensity of the emission peak of the high chromatic richness light source in this waveband based on the addition of the phosphor of this waveband.

Specifically, in this embodiment of the present invention, the high chromatic richness light source has seven phosphors with peak emission wavelengths greater than or equal to 490 nm and less than 680 nm, one phosphor with a peak emission wavelength greater than or equal to 680 nm and less than or equal to 780 nm, and three phosphors with peak emission wavelengths greater than 780 nm and less than or equal to 850 nm.

Wherein, the seven phosphors with peak emission wavelengths greater than or equal to 490 nm and less than 680 nm specifically are phosphors with peak emission wavelengths of 494 nm, 495 nm, 525 nm, 535 nm, 605 nm, 655 nm, and 675 nm, respectively. The one phosphor with a peak emission wavelength greater than or equal to 680 nm and less than or equal to 780 nm specifically is a phosphor with a peak emission wavelength of 733 nm, and the three phosphors with peak emission wavelengths greater than 780 nm and less than or equal to 850 nm specifically are phosphors with peak emission wavelengths of 795 nm, 821 nm, and 850 nm, respectively.

Furthermore, based on the corresponding color temperature design requirement, in this embodiment of the present invention, in order of increasing peak emission wavelength, a specific weight ratio of the eleven phosphors is: 0.27:0.097:2.86:14.28:2.4:0.67:0.84:4:2:1:1. A power ratio between the four LED chips with peak emission wavelengths greater than or equal to 380 nm and less than 430 nm, the four LED chips with peak emission wavelengths greater than or equal to 430 nm and less than 490 nm, and the six LED chips with peak emission wavelengths greater than or equal to 680 nm and less than or equal to 780 nm is 1:11.4:3. The high chromatic richness light source can form an emission spectrum corresponding to FIG. 2 at a correlated color temperature of 2700K, so that the chromatic spectrum of the high chromatic richness light source also has high richness and an appropriate intensity distribution throughout the entire visible light range, thereby facilitating reflection of light converging to the chromatic spectrum of an object when the high chromatic richness light source is used as an illumination light source to illuminate an object of any chromatic spectrum, and thus obtaining a natural, realistic, and comfortable visual experience when the high chromatic richness light source is used as an illumination light source.

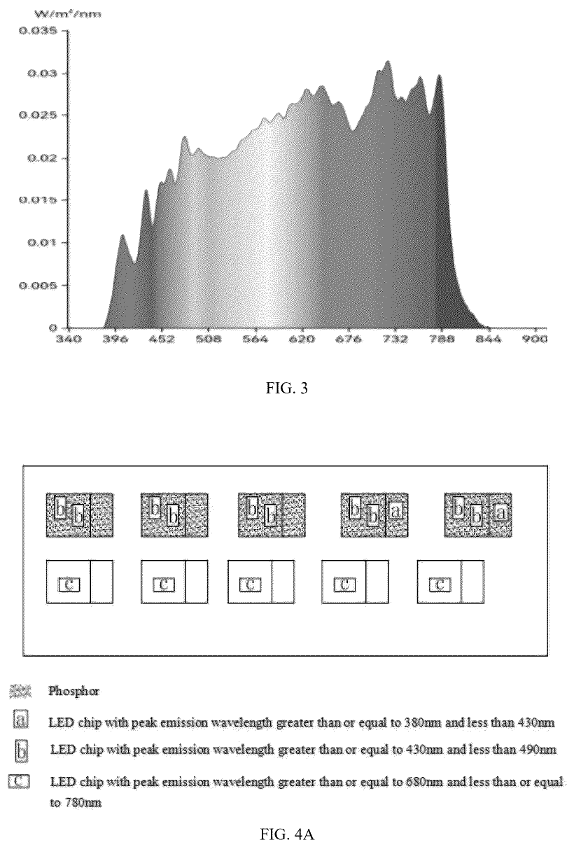

Specifically, in another embodiment of the present invention, the high chromatic richness light source can further obtain an emission spectrum corresponding to FIG. 3 at a correlated color temperature of 4000K based on the mixing of the luminous spectra of the high chromatic richness light sources in the aforementioned two embodiments, so that the chromatic spectrum of the high chromatic richness light source still has high richness and an appropriate intensity distribution throughout the entire visible light range.

That is to say, in some embodiments of the present invention, the high chromatic richness light source has at least two lighting modes based on the requirement of adjusting or selecting the correlated color temperature, wherein in at least one of the lighting mode, the LED chips emitting light and the phosphors packaged with the LED chips satisfy the requirements of having at least two LED chips with peak emission wavelengths greater than or equal to 380 nm and less than 430 nm, at least two types of LED chips with peak emission wavelengths greater than or equal to 430 nm and less than 490 nm, at least three phosphors with peak emission wavelengths greater than or equal to 490 nm and less than 680 nm, as well as at least two types of LED chips with peak emission wavelengths greater than or equal to 680 nm and less than or equal to 780 nm. For example, in at least one of the lighting mode, the LED chips emitting light and the phosphors encapsulated together with the LED chips correspond, in terms of quantity, peak emission wavelength, and phosphor weight ratio, to the high chromatic richness light source of any one of the first two embodiments of the present invention.

It is worth mentioning that, in the above embodiments of the present invention, the LED chips may adopt any one of conventional LED packaging forms such as 2835, 3014, 3030, 3528, 5050, COB, and LED strip, and the packaging forms of each LED chip are not limited to being the same.

In addition, the LED chips with emission peak wavelengths greater than or equal to 380 nm and less than 430 nm may be packaged independently or may be encapsulated together with at least one of the aforementioned phosphors; similarly, the LED chips with emission peak wavelengths greater than or equal to 680 nm and less than or equal to 780 nm may be packaged independently or may be encapsulated together with at least one of the aforementioned phosphors, which is not limited by the present invention. The LED chips with emission peak wavelengths greater than or equal to 430 nm and less than 490 nm are encapsulated together with the corresponding phosphors.

It is worth mentioning that, in a state where a combination of at least two types of the LED chips with emission peak wavelengths greater than or equal to 430 nm and less than 490 nm, at least three the phosphors with emission peak wavelengths greater than or equal to 490 nm and less than 680 nm, and at least two types of the LED chips with emission peak wavelengths greater than or equal to 680 nm and less than or equal to 780 nm can form white light based on the color discrimination mechanism of the human eye, an independently packaged of the LED chip with emission peak wavelength greater than or equal to 380 nm and less than 430 nm may cause a visual perception of purple light spots to the user. Therefore, the LED chips with emission peak wavelengths greater than or equal to 380 nm and less than 430 nm are preferably encapsulated together with at least one of the aforementioned phosphors, so as to facilitate ensuring a uniform distribution of purple light in the aforementioned “white light”, thereby obtaining a balanced and stable light color visual perception while improving the chromatic richness of the high chromatic richness light source.

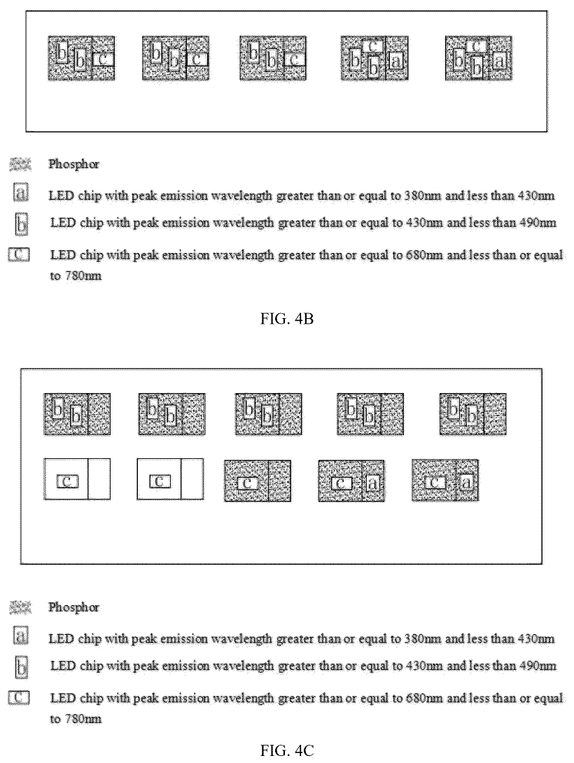

Specifically, taking an LED package as the packaging carrier for the LED chips and the phosphors, and corresponding to the structure in which the LED chips with emission peak wavelengths greater than or equal to 430 nm and less than 490 nm are encapsulated together with the corresponding phosphors and the LED chips with emission peak wavelengths greater than or equal to 380 nm and less than 430 nm are encapsulated together with at least one of the aforementioned phosphors, three exemplary packaging forms of the high chromatic richness light source are schematically shown in FIGS. 4A to 4C, respectively.

As shown in FIGS. 4A and 4B, in the LED packages encapsulating the LED chips with peak emission wavelengths greater than or equal to 430 nm and less than 490 nm, the corresponding phosphors are also encapsulated, while in the LED packages encapsulating the LED chips with peak emission wavelengths greater than or equal to 380 nm and less than 430 nm, the LED chips with peak emission wavelengths greater than or equal to 430 nm and less than 490 nm are also encapsulated. In this way, under the condition that the LED chips with peak emission wavelengths greater than or equal to 430 nm and less than 490 nm are encapsulated together with the corresponding phosphors, the structural feature of co-packaging the LED chips with peak emission wavelengths greater than or equal to 380 nm and less than 430 nm with at least one of the aforementioned phosphors is realized.

Specifically, in the exemplary packaging structure corresponding to FIG. 4A, the LED chips with peak emission wavelengths greater than or equal to 680 nm and less than or equal to 780 nm are individually encapsulated, that is, in the LED packages encapsulating the LED chips with peak emission wavelengths greater than or equal to 680 nm and less than or equal to 780 nm, neither the phosphors nor the LED chips with peak emission wavelengths greater than or equal to 380 nm and less than 430 nm or the LED chips with peak emission wavelengths greater than or equal to 430 nm and less than 490 nm are encapsulated. In the exemplary packaging structure corresponding to FIG. 4B, in the LED packages encapsulating the LED chips with peak emission wavelengths greater than or equal to 680 nm and less than or equal to 780 nm, the LED chips with peak emission wavelengths greater than or equal to 430 nm and less than 490 nm are also encapsulated, thereby realizing the structural feature of co-packaging the LED chips with peak emission wavelengths greater than or equal to 680 nm and less than or equal to 780 nm with at least one of the aforementioned phosphors.

As shown in FIG. 4C, in the LED packages encapsulating the LED chips with peak emission wavelengths greater than or equal to 430 nm and less than 490 nm, the corresponding phosphors are also encapsulated; in the LED packages encapsulating the LED chips with peak emission wavelengths greater than or equal to 380 nm and less than 430 nm, the LED chips with peak emission wavelengths greater than or equal to 680 nm and less than or equal to 780 nm and the corresponding phosphors are also encapsulated; and at least a portion of the LED packages are encapsulated with only the LED chips with peak emission wavelengths greater than or equal to 680 nm and less than or equal to 780 nm among the types of LED chips being encapsulated, the LED chips can either be individually encapsulated or encapsulated together with the corresponding phosphors. For example, corresponding to FIG. 4C, at least a portion of the LED packages that are encapsulated only with the LED chips having peak emission wavelengths greater than or equal to 680 nm and less than or equal to 780 nm among the types of the LED chips being packaged are further encapsulated together with the corresponding phosphors.

It is worth mentioning that, in the exemplary packaging structures shown in FIGS. 4A to 4C, the diagrams using LED packages as the packaging carrier for the LED chips and the phosphors are merely exemplary illustrations of the types of LED chips encapsulated in the LED packages and whether the corresponding phosphors are encapsulated together, and the quantities of the corresponding LED chips encapsulated in each of the LED package shown in the figures do not constitute a limitation to the present invention.

Those skilled in the art should understand that the embodiments of the present invention described above and shown in the drawings are provided merely as examples and do not limit the present invention. The objectives of the present invention have been fully and effectively achieved. The functional and structural principles of the present invention have been demonstrated and described in the embodiments, and without departing from the principles, the embodiments of the present invention may be subject to any modifications or alterations.

What is claimed is:

1. A high chromatic richness light source, wherein said high chromatic richness light source has:
at least two peak emission wavelengths generated by LED chips within a waveband greater than or equal to 380 nm and less than 430 nm, with a mutual peak wavelength difference greater than or equal to 5 nm;
at least two peak emission wavelengths generated by LED chips within a waveband greater than or equal to 430 nm and less than 490 nm, with a mutual peak wavelength difference greater than or equal to 5 nm; and
at least three peak emission wavelengths generated by phosphors within a waveband greater than or equal to 490 nm and less than 680 nm, with a mutual peak wavelength difference greater than or equal to 5 nm; as well as
at least two peak emission wavelengths generated by LED chips within a waveband greater than or equal to 680 nm and less than or equal to 780 nm, with a mutual peak wavelength difference greater than or equal to 5 nm;
wherein when said high chromatic richness light source has at least two lighting modes, said LED chips are defined as light-emitting LED chips that operate in at least one lighting mode, and said phosphors are defined as phosphors packaged onto said light-emitting LED chips.

2. The high chromatic richness light source, as recited in claim 1, wherein said at least two peak emission wavelengths generated by LED chips within a waveband greater than or equal to 380 nm and less than 430 nm, with a mutual peak wavelength difference greater than or equal to 5 nm, are located in different wavebands among the following five wavebands:
a waveband greater than or equal to 380 nm and less than 390 nm,
a waveband greater than or equal to 390 nm and less than 400 nm,
a waveband greater than or equal to 400 nm and less than 410 nm,
a waveband greater than or equal to 410 nm and less than 420 nm, and
a waveband greater than or equal to 420 nm and less than 430 nm.

3. The high chromatic richness light source, as recited in claim 2, wherein said at least two peak emission wavelengths generated by LED chips within a waveband greater than or equal to 430 nm and less than 490 nm, with a mutual peak wavelength difference greater than or equal to 5 nm, are located in different wavebands among the following six wavebands:
a waveband greater than or equal to 430 nm and less than 440 nm,
a waveband greater than or equal to 440 nm and less than 450 nm,
a waveband greater than or equal to 450 nm and less than 460 nm,
a waveband greater than or equal to 460 nm and less than 470 nm,
a waveband greater than or equal to 470 nm and less than 480 nm, and
a waveband greater than or equal to 480 nm and less than 490 nm.

4. The high chromatic richness light source, as recited in claim 3, wherein a maximum difference between said at least three peak emission wavelengths generated by phosphors within a waveband greater than or equal to 490 nm and less than 680 nm, with a mutual peak wavelength difference greater than or equal to 5 nm, is greater than or equal to 50 nm, that is, a difference between a minimum peak emission wavelength and a maximum peak emission wavelength is greater than or equal to 50 nm.

5. The high chromatic richness light source, as recited in claim 4, wherein said at least two peak emission wavelengths generated by LED chips within a waveband greater than or equal to 680 nm and less than or equal to 780 nm, with a mutual peak wavelength difference greater than or equal to 5 nm, are located in different wavebands among the following ten wavebands:
a waveband greater than or equal to 680 nm and less than 690 nm,
a waveband greater than or equal to 690 nm and less than 700 nm,
a waveband greater than or equal to 700 nm and less than 710 nm,
a waveband greater than or equal to 710 nm and less than 720 nm,
a waveband greater than or equal to 720 nm and less than 730 nm,
a waveband greater than or equal to 730 nm and less than 740 nm,
a waveband greater than or equal to 740 nm and less than 750 nm,
a waveband greater than or equal to 750 nm and less than 760 nm,
a waveband greater than or equal to 760 nm and less than 770 nm, and
a waveband greater than or equal to 770 nm and less than or equal to 780 nm.

6. The high chromatic richness light source, as recited in claim 5, wherein said high chromatic richness light source has four LED chips with peak emission wavelengths greater than or equal to 380 nm and less than 430 nm, four LED chips with peak emission wavelengths greater than or equal to 430 nm and less than 490 nm, and six LED chips with peak emission wavelengths greater than or equal to 680 nm and less than or equal to 780 nm.

7. The high chromatic richness light source, as recited in claim 6, wherein said four LED chips with peak emission wavelengths greater than or equal to 380 nm and less than 430 nm have peak emission wavelengths respectively located in said waveband greater than or equal to 380 nm and less than 390 nm, said waveband greater than or equal to 390 nm and less than 400 nm, said waveband greater than or equal to 400 nm and less than 410 nm, and said waveband greater than or equal to 410 nm and less than 420 nm.

8. The high chromatic richness light source, as recited in claim 7, wherein among said four LED chips with peak emission wavelengths greater than or equal to 380 nm and less than 430 nm, LED chip with a peak emission wavelength located within said waveband greater than or equal to 380 nm and less than 390 nm has a power higher than that of any one of the other three LED chips.

9. The high chromatic richness light source, as recited in claim 8, wherein in order of increasing peak emission wavelength, a quantity ratio of said four LED chips with peak emission wavelengths greater than or equal to 380 nm and less than 430 nm is 2.4:1.4:1.2:1.

10. The high chromatic richness light source, as recited in claim 7, wherein said four LED chips with peak emission wavelengths greater than or equal to 430 nm and less than 490 nm have peak emission wavelengths respectively located in said waveband greater than or equal to 430 nm and less than 440 nm, said waveband greater than or equal to 440 nm and less than 450 nm, said waveband greater than or equal to 450 nm and less than 460 nm, and said waveband greater than or equal to 470 nm and less than 480 nm.

11. The high chromatic richness light source, as recited in claim 10, wherein in order of increasing peak emission wavelength, a quantity ratio of said four LED chips with peak emission wavelengths greater than or equal to 430 nm and less than 490 nm is 1:1:1:1.

12. The high chromatic richness light source, as recited in claim 10, wherein said six LED chips with peak emission wavelengths greater than or equal to 680 nm and less than or equal to 780 nm have peak emission wavelengths respectively located in said waveband greater than or equal to 700 nm and less than 710 nm, said waveband greater than or equal to 710 nm and less than 720 nm, said waveband greater than or equal to 730 nm and less than 740 nm, said waveband greater than or equal to 740 nm and less than 750 nm, said waveband greater than or equal to 750 nm and less than 760 nm, and said waveband greater than or equal to 770 nm and less than or equal to 780 nm.

13. The high chromatic richness light source, as recited in claim 12, wherein among said six LED chips with peak emission wavelengths greater than or equal to 680 nm and less than or equal to 780 nm, said LED chips with peak emission wavelengths located within said waveband greater than or equal to 770 nm and less than or equal to 780 nm outnumber said LED chips in any other single waveband of the other five.

14. The high chromatic richness light source, as recited in claim 13, wherein in order of increasing peak emission wavelength, a quantity ratio of said six LED chips with peak emission wavelengths greater than or equal to 680 nm and less than or equal to 780 nm is 1.3:1.6:1.6:1:3:5.

15. The high chromatic richness light source, as recited in claim 6, wherein said high chromatic richness light source has five phosphors with peak emission wavelengths greater than or equal to 490 nm and less than 680 nm.

16. The high chromatic richness light source, as recited in claim 15, wherein said five phosphors with peak emission wavelengths greater than or equal to 490 nm and less than 680 nm are phosphors with peak emission wavelengths of 494 nm, 495 nm, 525 nm, 535 nm, and 655 nm, respectively.

17. The high chromatic richness light source, as recited in claim 16, wherein in order of increasing peak emission wavelength, a weight ratio of said five phosphors with peak emission wavelengths greater than or equal to 490 nm and less than 680 nm is 0.22:0.22:0.55:5.94:0.887.

18. The high chromatic richness light source, as recited in claim 12, wherein a power ratio between said four LED chips with peak emission wavelengths greater than or equal to 380 nm and less than 430 nm, said four LED chips with peak emission wavelengths greater than or equal to 430 nm and less than 490 nm, and said six LED chips with peak emission wavelengths greater than or equal to 680 nm and less than or equal to 780 nm is 1:10.3:3.7.

19. The high chromatic richness light source, as recited in claim 5, wherein said high chromatic richness light source further has at least two phosphors with peak emission wavelengths greater than 780 nm and less than or equal to 850 nm, and a maximum difference between peak emission wavelengths of different phosphors is greater than or equal to 30 nm, a peak emission wavelength difference between a phosphor with the smallest peak emission wavelength and a phosphor with the largest peak emission wavelength is greater than or equal to 30 nm.

20. The high chromatic richness light source, as recited in claim 19, wherein said high chromatic richness light source further has at least one phosphor with a peak emission wavelength greater than or equal to 680 nm and less than or equal to 780 nm.

21. The high chromatic richness light source, as recited in claim 20, wherein said high chromatic richness light source has seven phosphors with peak emission wavelengths greater than or equal to 490 nm and less than 680 nm, one phosphor with a peak emission wavelength greater than or equal to 680 nm and less than or equal to 780 nm, and three phosphors with peak emission wavelengths greater than 780 nm and less than or equal to 850 nm.

22. The high chromatic richness light source, as recited in claim 21, wherein said seven phosphors with peak emission wavelengths greater than or equal to 490 nm and less than 680 nm are specifically phosphors with peak emission wavelengths of 494 nm, 495 nm, 525 nm, 535 nm, 605 nm, 655 nm, and 675 nm, respectively; said one phosphor with a peak emission wavelength greater than or equal to 680 nm and less than or equal to 780 nm is specifically a phosphor with a peak emission wavelength of 733 nm; said three phosphors with peak emission wavelengths greater than 780 nm and less than or equal to 850 nm are specifically phosphors with peak emission wavelengths of 795 nm, 821 nm, and 850 nm, respectively.

23. The high chromatic richness light source, as recited in claim 22, wherein in order of increasing peak emission wavelength, a specific weight ratio of eleven phosphors is 0.27:0.097:2.86:14.28:2.4:0.67:0.84:4:2:1:1.

24. The high chromatic richness light source, as recited in claim 5, wherein said LED chips with peak emission wavelengths greater than or equal to 430 nm and less than 490 nm are encapsulated together with corresponding phosphors, said LED chips with peak emission wavelengths greater than or equal to 380 nm and less than 430 nm are encapsulated together with at least one of said phosphors.

25. The high chromatic richness light source, as recited in claim 24, wherein LED packages serve as packaging carriers for said LED chips and said phosphors, in said LED packages encapsulating with said LED chips with peak emission wavelengths greater than or equal to 430 nm and less than 490 nm, said corresponding phosphors are also encapsulated, while in said LED packages encapsulating with said LED chips with peak emission wavelengths greater than or equal to 380 nm and less than 430 nm, said LED chips with peak emission wavelengths greater than or equal to 430 nm and less than 490 nm are also encapsulated.

26. The high chromatic richness light source, as recited in claim 25, wherein said LED chips with peak emission wavelengths greater than or equal to 680 nm and less than or equal to 780 nm are individually encapsulated, corresponding to said LED packages encapsulating said LED chips with peak emission wavelengths greater than or equal to 680 nm and less than or equal to 780 nm, neither said phosphors nor said LED chips with peak emission wavelengths greater than or equal to 380 nm and less than 430 nm or said LED chips with peak emission wavelengths greater than or equal to 430 nm and less than 490 nm are encapsulated.

27. The high chromatic richness light source, as recited in claim 25, wherein in said LED packages encapsulating said LED chips with peak emission wavelengths greater than or equal to 680 nm and less than or equal to 780 nm, said LED chips with peak emission wavelengths greater than or equal to 430 nm and less than 490 nm are also encapsulated.

28. The high chromatic richness light source, as recited in claim 24, wherein LED packages serve as packaging carriers for said LED chips and said phosphors, in said LED packages encapsulating said LED chips with peak emission wavelengths greater than or equal to 430 nm and less than 490 nm, said corresponding phosphors are also encapsulated, while said LED packages encapsulating said LED chips with peak emission wavelengths greater than or equal to 380 nm and less than 430 nm, said LED chips with peak emission wavelengths greater than or equal to 680 nm and less than or equal to 780 nm and said corresponding phosphors are also encapsulated, and at least a portion of said LED packages are encapsulated with only said LED chips with peak emission wavelengths greater than or equal to 680 nm and less than or equal to 780 nm among the types of said LED chips being encapsulated.

29. The high chromatic richness light source, as recited in claim 28, wherein at least a portion of said LED packages that are encapsulated only with said LED chips with peak emission wavelengths greater than or equal to 680 nm and less than or equal to 780 nm among the types of said LED chips being encapsulated are further encapsulated together with said corresponding phosphors.
